(19) United States
(12) Patent Application Publication
(10) Pub. No.: US 2011/0120534 A1
(43) Pub. Date: May 26, 2011

(54) THIN FILM SOLAR CELL AND MANUFACTURING METHOD THEREOF

(75) Inventor: Chin-Yao Tsai, Tainan County (TW)

(73) Assignee: AURIA SOLAR CO., LTD., Tainan (TW)

(21) Appl. No.: 12/951,070

(22) Filed: Nov. 22, 2010

(30) Foreign Application Priority Data
Nov. 20, 2009 (TW) 98139545
Nov. 20, 2009 (TW) 98139564

(51) Int. Cl. H01L 31/02; H01L 31/0224

(52) U.S. Cl. 136/252; 136/256; 438/98; 257/E31.124

(57) ABSTRACT

A thin film solar cell including a substrate, a first conductive layer, a photovoltaic layer, an interlayer and a second conductive layer is provided. The first conductive layer is disposed on the substrate. The photovoltaic layer is disposed on the first conductive layer. A plurality of electron-hole pairs are generated as the photovoltaic layer is illuminated. The interlayer disposed between the first conductive layer and the photovoltaic layer reduces dangling bonds on the surface of the photovoltaic layer, so as to prevent surface recombination of the electron-hole pairs from occurring on the surface of the photovoltaic layer. The second conductive layer is disposed on the photovoltaic layer. A manufacturing method of the thin film solar cell is also provided.

### CROSS-REFERENCE TO RELATED APPLICATION

This application claims the priority benefits of Taiwan application serial no. 98139564, filed on Nov. 20, 2009 and Taiwan application serial no. 98139545, filed on Nov. 20, 2009. The entirety of each of the above-mentioned patent applications is hereby incorporated by reference herein and made a part of specification.

### BACKGROUND OF THE INVENTION

1. Field of Invention

The present invention relates to a solar cell and a manufacturing method thereof, and more generally to a thin film solar cell with higher photoelectric conversion efficiency and a manufacturing method thereof.

2. Description of Related Art

Solar cells using monocrystalline silicon or polycrystalline silicon account for more than 90% in the solar cell market. However, these solar cells are made from silicon wafers of 150 μm to 350 μm thick, and the process cost thereof is higher. In addition, the raw materials of solar cells are silicon ingots with high quality. The silicon ingots face the shortage problem as the usage quantity thereof is increased significantly in recent years. Therefore, the thin film solar cell has been the new focus due to the advantages of low cost, easy for large-area production and simple module process, etc.

Generally speaking, in a conventional thin film solar cell, an electrode layer, a photovoltaic layer and another electrode layer are sequentially blanket-stacked on a substrate. During the process of stacking these layers, these layers are patterned by performing laser cutting processes, so as to form a plurality of sub cells connected in series. When a light enters the thin film solar cell from outside, free electron-hole pairs are generated in the photovoltaic layer by the solar energy, and the internal electric field formed by the PN junction makes electrons and holes respectively move toward two layers, so as to generate a storage state of electricity. Meanwhile, if a load circuit or an electronic device is connected, the electricity can be provided to drive the circuit or device.

However, a plurality of dangling bonds are usually present on the surface of the photovoltaic layer, so that the surface recombination of the electron-hole pairs generated by illumination on the photovoltaic layer easily occurs near the surface of the photovoltaic layer, and thus, the photoelectric conversion efficiency of the thin film solar cell is reduced. Accordingly, more attention has been drawn on how to solve the above-mentioned problem so as to improve the photoelectric conversion efficiency and electrical performance of the conventional thin film solar cell.

### SUMMARY OF THE INVENTION

The present invention provide a thin film solar cell to reduce the dangling bonds between film layers, and thus, recombination of electron-hole pairs on the surface is avoided and the photoelectric conversion efficiency of the thin film solar cell is further improved.

The present invention provides a manufacturing method to form the above-mentioned thin film solar cell.

The present invention provides a thin film solar cell including a substrate, a first conductive layer, a photovoltaic layer, an interlayer and a second conductive layer. The first conductive layer is disposed on the substrate. The photovoltaic layer is disposed on the first conductive layer. A plurality of electron-hole pairs are generated as the photovoltaic layer is illuminated. The interlayer disposed between the first conductive layer and the photovoltaic layer reduces dangling bonds on the surface of the photovoltaic layer, so as to prevent surface recombination of the electron-hole pairs from occurring on the surface of the photovoltaic layer. The second conductive layer is disposed on the photovoltaic layer.

According to an embodiment of the present invention, the thickness of the interlayer is more than zero angstrom (Å) and less than or equal to 1,000 angstroms.

According to an embodiment of the present invention, the material of the interlayer is a dielectric material, an insulating material or an oxygen-containing compound. According to an embodiment of the present invention, the material of the interlayer includes silicon oxide, silicon nitride or silicon oxynitride.

The present invention provides a manufacturing method of a thin film solar cell. A substrate is provided. A first conductive layer is formed on the substrate. An interlayer is formed on the first conductive layer. A photovoltaic layer is formed on the interlayer. The interlayer disposed between the first conductive layer and the photovoltaic layer reduces dangling bonds on the surface of the photovoltaic layer, so as to prevent surface recombination of electron-hole pairs from occurring on the surface of the photovoltaic layer. A second conductive layer is formed on the photovoltaic layer.

According to an embodiment of the present invention, after the step of forming the interlayer on the first conductive layer, the manufacturing method further includes performing a laser process to pattern the interlayer and the first conductive layer, so as to form a plurality of first openings to expose the substrate. According to an embodiment of the present invention, before the step of forming the interlayer on the first conductive layer, the manufacturing method further includes performing a laser process to pattern the first conductive layer, so as to form a plurality of first openings to expose the substrate.

According to an embodiment of the present invention, the method of forming the interlayer includes performing an oxidation process or a deposition process.

According to an embodiment of the present invention, after the step of forming the photovoltaic layer on the first conductive layer, the manufacturing method further includes performing a laser process to pattern the photovoltaic layer, so as to form a plurality of second openings to expose the first conductive layer.

According to an embodiment of the present invention, after the step of forming the second conductive layer on the photovoltaic layer, the manufacturing method further includes performing a laser process to pattern the photovoltaic layer and the second conductive layer, so as to form a plurality of third openings to expose the first conductive layer.

The present invention further provides a thin film solar cell including a substrate, a first conductive layer, a photovoltaic layer, a second conductive layer and a protection layer. The first conductive layer is disposed on the substrate and has a plurality of first openings to expose a portion of the substrate. The photovoltaic layer is disposed on the first conductive layer and has a plurality of second openings to expose a portion of the first conductive layer. The photovoltaic layer is physically connected to the substrate through the first openings. The second conductive layer is disposed on the photovoltaic layer and has a plurality of third openings to expose a portion of the first conductive layer and a portion of a side surface of the photovoltaic layer. The third openings and a portion of the second openings are disposed at the same positions, and the second conductive layer is physically connected to the first conductive layer through the second openings. The protection layer is disposed on the photovoltaic layer, opposite to the first conductive layer and between the photovoltaic layer and the second conductive layer.

According to an embodiment of the present invention, the thickness of the protection layer is more than zero angstrom and less than or equal to 1,000 angstroms. According to an embodiment of the present invention, the material of the protection layer is a dielectric material, an insulating material or an oxygen-containing compound.

According to an embodiment of the present invention, the material of the protection layer includes silicon oxide, silicon nitride or silicon oxynitride.

The present invention also provides a manufacturing method of a thin film solar cell. A substrate is provided. A first conductive layer is formed on the substrate. A plurality of first openings are formed in the first conductive layer, wherein the first openings expose a portion of the substrate. A photovoltaic layer is formed on the first conductive layer, wherein the photovoltaic layer is physically connected to the substrate through the first openings. A protection layer is formed on the photovoltaic layer. A second conductive layer is formed on the protection layer.

According to an embodiment of the present invention, after the step of forming the protection layer on the photovoltaic layer, the manufacturing method further includes forming a plurality of second openings in the photovoltaic layer, wherein the second openings expose a portion of the first conductive layer. According to an embodiment of the present invention, after the step of forming the second conductive layer on the protection layer, the manufacturing method further includes forming a plurality of third openings in the second conductive layer, wherein the third openings expose a portion of the first conductive layer and a portion of a side surface of the photovoltaic layer, and the second conductive layer is physically connected to the first conductive layer through the second openings. According to an embodiment of the present invention, the methods of forming the first, second and third openings respectively include performing a laser process.

According to an embodiment of the present invention, the method of forming the protection layer includes performing a plasma oxidation process.

According to an embodiment of the present invention, the method of forming the protection layer includes performing a deposition process, a print screening process, a dry film lamination process or a coating process.

According to an embodiment of the present invention, the method of forming the first conductive layer includes forming at least one of a transparent conductive layer and a reflective layer on the substrate, and the second conductive layer is a transparent conductive layer.

According to an embodiment of the present invention, the method of forming the second conductive layer includes forming at least one of a transparent conductive layer and a reflective layer on the photovoltaic layer, and the first conductive layer is a transparent conductive layer.

In view of the above, in the thin film solar cell of the present invention, the interlayer disposed between the photovoltaic layer and the first conductive layer reduces the dangling bonds on the surface of the photovoltaic layer, so as to reduce the possibility of the recombination of electron-hole pairs on the surface of the photovoltaic layer. Accordingly, the photoelectric conversion efficiency and electrical performance of the thin film solar cell are further improved.

In addition, in the thin film solar cell of the present invention, the protection layer disposed between the photovoltaic layer and the second conductive layer reduces the dangling bonds on the contact surface between film layers, so as to reduce the possibility of the recombination of electron-hole pairs at the interface between the photovoltaic layer and the second conductive layer. Accordingly, the photoelectric conversion efficiency and electrical performance of the thin film solar cell are further improved. Besides, the present invention also provides a manufacturing method to form the above-mentioned thin film solar cell.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a cross-sectional view of a thin film solar cell according to an embodiment of the present invention.

FIG. 2 schematically illustrates film layers of the photovoltaic layer in FIG. 1 according to an embodiment.

FIGS. 3A to 3I schematically illustrate a process flow of manufacturing a thin film solar cell according to an embodiment of the present invention.

FIG. 4 schematically illustrates a cross-sectional view of a thin film solar cell according to another embodiment of the present invention.

FIG. 5 schematically illustrates a cross-sectional view of a thin film solar cell according to another embodiment of the present invention.

FIG. 6 schematically illustrates film layers of a photovoltaic layer of a thin film solar cell.

FIGS. 7A to 7H schematically illustrate a process flow of manufacturing a thin film solar cell according to another embodiment of the present invention.

FIGS. 8A to 8B schematically illustrate a process flow of manufacturing a thin film solar cell according to another embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

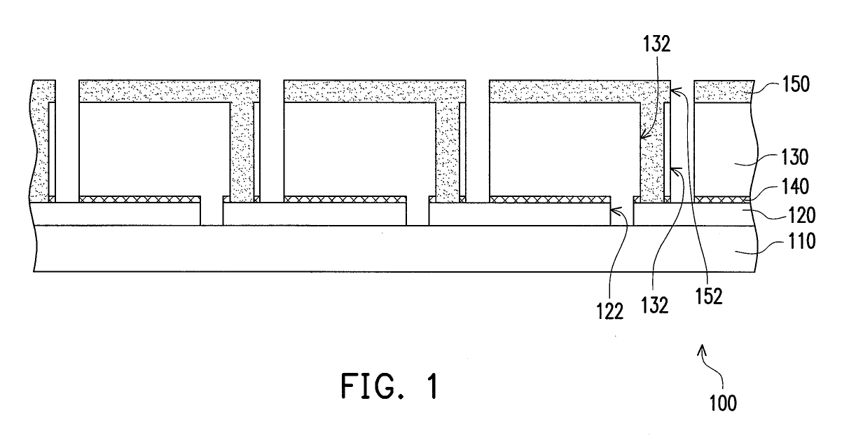

FIG. 1 schematically illustrates a cross-sectional view of a thin film solar cell according to an embodiment of the present invention. Referring to FIG. 1, in this embodiment, the thin film solar cell 100 includes a substrate 110, a first conductive layer 120, an interlayer 140, a photovoltaic layer 130 and a second conductive layer 150. In this embodiment, the substrate 110 can be a transparent substrate, such as a glass substrate.

The first conductive layer 120 is disposed on the substrate 110, as shown in FIG. 1. In this embodiment, the first conductive layer 120 has a plurality of first openings 122 to expose a portion of the substrate 110. The first conductive layer 120 having the first openings 122 usually serves as front electrodes of a plurality of sub cells. In this embodiment, the first conductive layer 120 can be a transparent conductive layer, and the material thereof is at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO), for example.

In another embodiment (not shown), the first conductive layer 120 can be a stacked layer of a reflective layer (not shown) and the above-mentioned transparent conductive layer, and the reflective layer is disposed between the transparent conductive layer and the substrate 110. The material of the reflective layer can be metal with higher reflectivity, such as aluminium (Al), silver (Ag), molybdenum (Mo) or copper (Cu).

Referring to FIG. 1, the photovoltaic layer 130 is disposed on the first conductive layer 120, and a plurality of electron-hole pairs are generated as the photovoltaic layer 130 is illuminated. In this embodiment, the photovoltaic layer 130 has a plurality of second openings 132 to expose a portion of the first conductive layer 120. The photovoltaic layer 130 is physically connected to the substrate 110 through the first openings 122. The photovoltaic layer 130 having the second openings 132 usually serves as a photoelectric conversion layer (or light absorption layer) in the plurality of sub cells connected in series. In this embodiment, the photovoltaic layer 130 can be a Group IV thin film, a III-V compound semiconductor thin film, a II-VI compound semiconductor thin film or an organic compound semiconductor thin film. In details, the Group IV thin film includes at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem silicon thin film and a triple silicon thin film, for example. The III-V compound semiconductor thin film includes a gallium arsenide (GaAs) thin film, an indium gallium phosphide (InGaP) thin film or a combination thereof, for example. The II-VI compound semiconductor thin film can be a copper indium diselenide (CIS) thin film, a copper indium gallium diselenide (CIGS) thin film, a cadmium telluride (CdTe) thin film or a combination thereof, for example. The organic compound semiconductor thin film includes a mixture of poly(3-hexylthiophene) (P3HT) and PCBM, for example.

That is, the thin film solar cell 100 can at least include the film layer structure of an amorphous silicon thin film solar cell, a microcrystalline silicon thin film solar cell, a tandem thin film solar cell, a triple thin film solar cell, a CIS thin film solar cell, a CIGS thin film solar cell, a GdTe thin film solar cell or an organic thin film solar cell. In other words, the photovoltaic layer 130 of this embodiment is provided only for illustration purposes, and can be decided according to the users' requirements. The thin film solar cell 100 can also include the film layer structure of another suitable thin film solar cell.

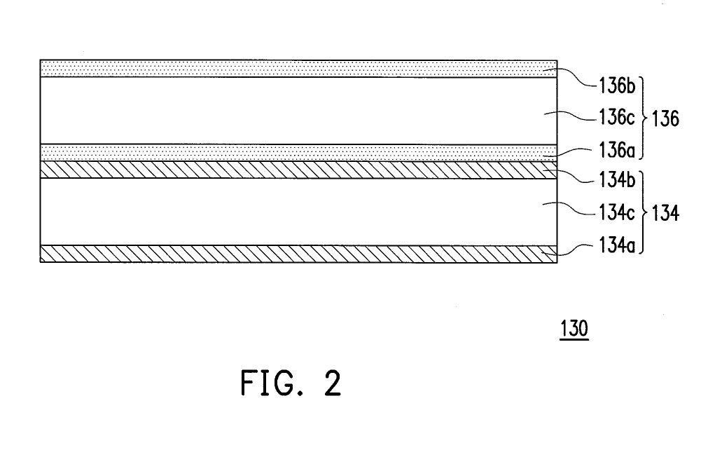

When a tandem thin film solar cell is taken as an example, the photovoltaic layer 130 can be a first semiconductor stacked layer 134 with a second semiconductor stacked layer 136 stacked thereon, as shown in FIG. 2. The first semiconductor stacked layer 134 has a first-type semiconductor layer 134a, a second-type semiconductor layer 134b and a first intrinsic layer 134c, for example. The second semiconductor stacked layer 136 has a third-type semiconductor layer 136a, a fourth-type semiconductor layer 136b and a second intrinsic layer 136c, for example. The first-type semiconductor layer 134a of the first semiconductor stacked layer 134 and the third-type semiconductor layer 136a of the second semiconductor stacked layer 136 can be P-type semiconductor layers, while the third-type semiconductor layer 134b of the first semiconductor stacked layer 134 and the fourth-type semiconductor layer 136b of the second semiconductor stacked layer 136 can be N-type semiconductor layers. In other words, in this embodiment, the first semiconductor stacked layer 134 and the second semiconductor stacked layer 136 form a PIN semiconductor stacked structure. However, the present invention is not limited thereto.

In another embodiment, the first-type semiconductor layer 134a of the first semiconductor stacked layer 134 and the third-type semiconductor layer 136a of the second semiconductor stacked layer 136 can be N-type semiconductor layers, while the third-type semiconductor layer 134b of the first semiconductor stacked layer 134 and the fourth-type semiconductor layer 136b of the second semiconductor stacked layer 136 can be P-type semiconductor layers. In addition, in another embodiment, the first semiconductor stacked layer 134 and the second semiconductor stacked layer 136 described above do not have the first intrinsic layer 134c and the second intrinsic layer 136c and form a PN semiconductor stacked structure.

Moreover, when the photovoltaic layer 130 of the thin film solar cell 100 is a tandem structure, the material of the first semiconductor stacked layer 134 can be amorphous silicon, and the material of the second semiconductor stacked layer 136 can be microcrystalline silicon. The materials of the first semiconductor stacked layer 134 and the second semiconductor stacked layer 136 are provided only for illustration purposes. It is for sure that the material of the first semiconductor stacked layer 134 can be changed with that of the second semiconductor stacked layer 136 according to the users' requirements and designs.

Referring to FIG. 1, the interlayer 140 is disposed between the first conductive layer 120 and the photovoltaic layer 130, so as to reduce the dangling bonds on the surface of the photovoltaic layer 130 to prevent surface recombination of the electron-hole pairs from occurring on the surface of the photovoltaic layer 130. In this embodiment, the interlayer 140 is mainly for reducing the recombination of the electron-hole pairs and the dangling bonds on the surface of the photovoltaic layer 130, and thus, the possibility of the surface recombination is lowered, and the electrical performance and photoelectric conversion efficiency of the thin film solar cell 100 are further improved. In details, the so-called dangling bonds are present on the surface of the photovoltaic layer 130. Further, the electron-hole pairs excited by illumination on the photovoltaic layer 130 are recombined with the dangling bonds on the surface of the photovoltaic layer 130. Therefore, as the thin film solar cell is illuminated, the electrical performance and photovoltaic conversion efficiency thereof are limited.

In other words, in this embodiment, the interlayer 140 is disposed between the photovoltaic layer 130 and the first conductive layer 120, so as to reduce or lower the dangling bonds on the surface of the photovoltaic layer 130 by bonding the atoms of the interlayer 140 to the dangling bonds. Accordingly, the possibility of the surface recombination of the electron-hole pairs generated by illumination on the photovoltaic layer 130 and the dangling bonds on the surface of the photovoltaic layer 130 is reduced, and the whole photoelectric conversion efficiency of the thin film solar cell 100 is further improved.

In addition, the interlays 140 has better performance as the thickness thereof is substantially more than zero angstrom and less than or equal of 1,000 angstroms. The material of the interlays 140 can be a dielectric material, an insulating material or an oxygen-containing compound. For example, the material of the interlayer 140 can be an insulating material such as silicon oxide, silicon nitride or silicon oxynitride. The interlayer 140 has a thickness allowing to transmit the electron-hole pairs provided by the photovoltaic layer 130 to the first conductive layer 120. That is, the interlayer 140 has a thickness such that the photovoltaic layer 130 is not electrically insulated from the first conductive layer 120.

It is noted that when the material of the first semiconductor stacked layer 134 is amorphous silicon, the material of the interlayer 140 is preferably nitride; when the material of the first semiconductor stacked layer 134 is microcrystalline silicon or polycrystalline silicon, the material of the interlayer 140 is preferably oxide.

Referring to FIG. 1 again, the second conductive layer 150 is disposed on the photovoltaic layer 130. In this embodiment, the second dielectric layer 150 has a plurality of third openings 152 to expose a portion of the first conductive layer 120 and a portion of the side surface of the photovoltaic layer 130. The third openings 152 and a portion of the second openings 132 are disposed at the same positions, and the second conductive layer 150 is physically connected to the first conductive layer 120 through the second openings 132. Further, the second conductive layer 150 can include the material of the above-mentioned transparent conductive layer, and the details are not iterated herein. In this embodiment, the second conductive layer 150 can further include a reflective layer disposed on the transparent conductive layer.

It is noted that when the second conductive layer 150 includes a reflective layer, the first conductive layer 120 can only be a transparent conductive layer. On the contrary, when the first conductive layer 120 includes a reflective layer, the second conductive layer 150 can only be a transparent conductive layer without a reflective layer thereon. In another embodiment, each of the first conductive layer 120 and the second conductive layer 150 can be a single transparent conductive layer without a reflective layer thereon. In other words, the design of the first conductive layer 120 and the second conductive layer 150 can be adjusted by the users' requirements (e.g. for manufacturing a thin film solar cell with double-sided illumination or a thin film solar cell with one-sided illumination). The design of the first conductive layer 120 and the second conductive layer 150 described above is provided only for illustration purposes, and is not construed as limiting the present invention.

In view of the above, the thin film solar cell 100 is irradiated by light (not shown) to generate electron-hole pairs. The thin film solar cell 100 has the interlayer 140 disposed between the photovoltaic layer 130 and the first conductive layer 120, and the interlayer 140 can effectively reduce or lower the dangling bonds on the surface of the photovoltaic layer 130. Accordingly, the possibility of the recombination of the electron-hole pairs on the surface of the photovoltaic layer 130 is decreased. In other words, as compared with the conventional thin film solar cell without the interlayer 140, the thin film solar cell 100 with the interlayer 140 obtains a significant improvement in the photoelectric conversion efficiency and electrical performance.

In addition, the present invention also provides a manufacturing method to form the above-mentioned thin film solar cell 100, which is described in the following.

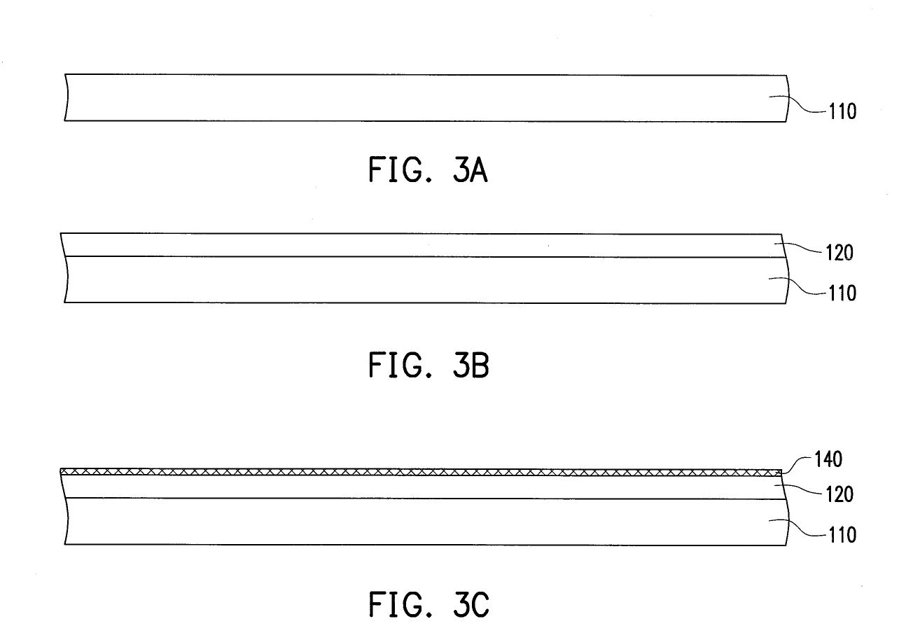

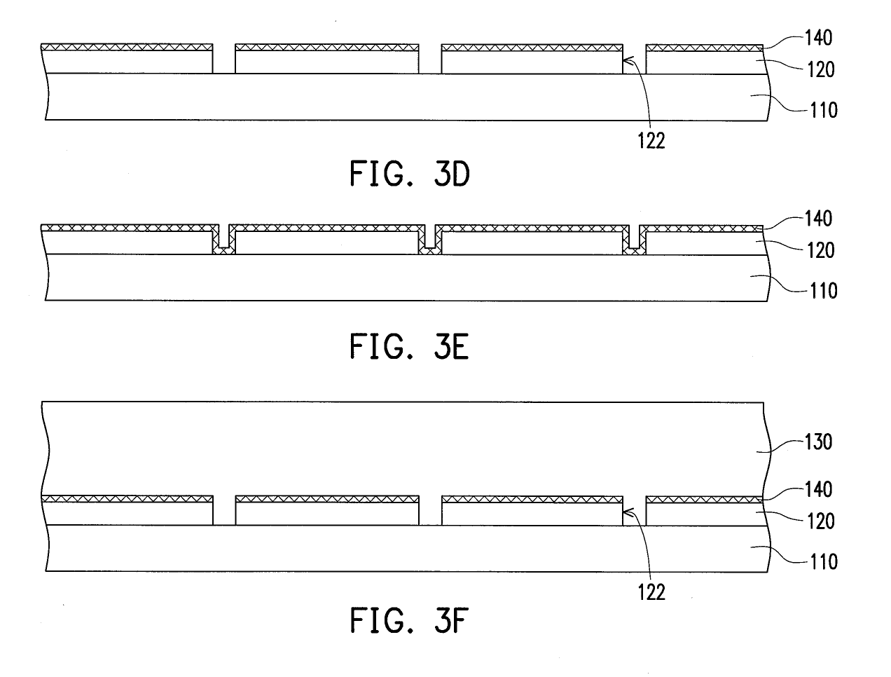

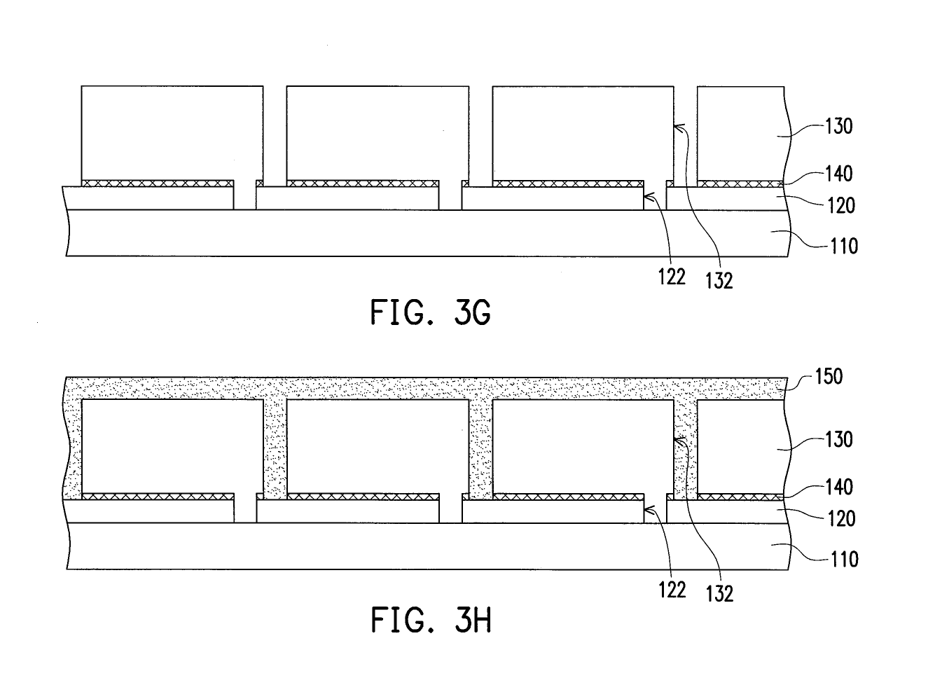

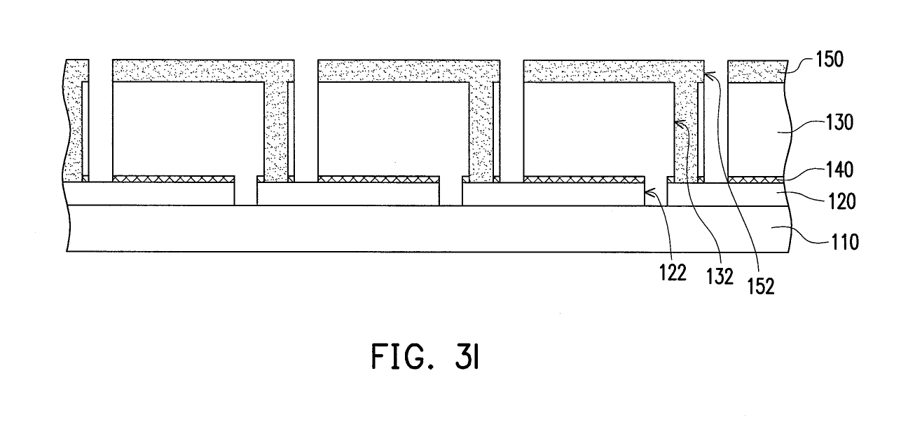

FIGS. 3A to 3I schematically illustrate a process flow of manufacturing a thin film solar cell according to an embodiment of the present invention. Referring to FIG. 3A, the above-mentioned substrate 110 is provided. The substrate 110 can be a transparent substrate, such as a glass substrate.

Referring to FIG. 3B, the above-mentioned first conductive layer 120 is formed on the substrate 110. The first conductive layer 120 includes the material of the above-mentioned transparent conductive layer, and the forming method thereof is by performing a sputtering process, a metal organic chemical vapour deposition (MOCVD) process or an evaporation process, for example.

Thereafter, the above-mentioned interlayer 140 is formed on the first conductive layer 120, as shown in FIG. 3C. In this embodiment, the method of forming the interlayer 140 adopts an oxidation process or a deposition process, for example. The material of the interlayer 140 can be the above-mentioned material, and the details are not iterated herein. It is noted that the method of forming the interlayer 140 described above is provided only for illustration purposes, and is not construed as limiting the present invention. The method of forming the interlayer 140 can be decided according to the users' requirements and the material of the interlayer 140. In addition, the thickness of the interlayer 140 is limited in the above-mentioned range, and the details are not iterated herein.

Referring to FIG. 3D, the above-mentioned first openings 122 are formed in the first conductive layer 120 and the interlayer 140 to expose a portion of the substrate 110. Accordingly, front electrodes of a plurality of sub cells connected in series are formed. In this embodiment, the method of forming the first openings 122 is by patterning the first conductive layer 120 and the interlayer 140 with a laser process, for example.

In another embodiment, before the step of forming the interlayer 140 on the first conductive layer 120, a laser process can be performed to the first conductive layer 120, so as to form the above-mentioned first openings 122 to expose a portion of the substrate 110. Accordingly, front electrodes of a plurality of sub cells connected in series are formed. Thereafter, the interlayer 140 is formed on the first conductive layer 120, as shown in FIG. 3E. The process steps and sequence described above are provided only for illustration purposes, and is not construed as limiting the present invention. The process steps and sequence of this part are decided according to the users' requirements.

Referring to FIG. 3F, the above-mentioned photovoltaic layer 130 is formed on the interlayer 140. In this embodiment, the method of forming the photovoltaic layer 130 is by sequentially forming the first semiconductor stacked layer 134 and the second semiconductor stacked layer 136 described above on the interlayer 140. Accordingly, a photovoltaic layer as a tandem structure is formed. In details, the method of forming the photovoltaic layer 130 is by performing a radio frequency plasma enhanced chemical vapour deposition (RF PECVD) process, a vary high frequency plasma enhanced chemical vapour deposition (VHF CVD) process or a microwave plasma enhanced chemical vapour deposition (MW PECVD) process, for example. The above-mentioned forming method of the photovoltaic layer 130 is provided only for illustration purposes, and is not construed as limiting the present invention. The forming method of the photovoltaic layer 130 can be adjusted depending on the film layer design (e.g. the structure of the above-mentioned Group IV thin film or II-VI compound semiconductor thin film) of the photovoltaic layer 130. Further, the deposition thicknesses of the first semiconductor stacked layer 134 and the second semiconductor stacked layer 136 can be decided according to the users' requirements.

Referring to FIG. 3G, the above-mentioned second openings 132 are formed in the photovoltaic layer 130 to expose a portion of the first conductive layer 120. The photovoltaic layer 130 is physically connected to the substrate 110 through the first openings 122. In this embodiment, the method of forming the second openings 132 is by patterning the photovoltaic layer 130 with a laser process, for example.

Referring to FIG. 3H, the above-mentioned second conductive layer 150 is formed on the photovoltaic layer 130 and in the second openings 132, and covers the portion of the first conductive layer 120 exposed by the second openings 132. In this embodiment, the second conductive layer 150 and the first conductive layer 130 have the same forming method. That is, the method of forming the second conductive layer 150 is by performing the above-mentioned sputtering process, MOCVD process, or evaporation process, for example. The material of the second conductive layer 150 is the material of the above-mentioned transparent conductive layer, and the details are not iterated herein.

Referring to FIG. 31, the above-mentioned third openings 152 are formed in the second conductive layer 150 to expose a portion of the first conductive layer 120 and a portion of the side surface of the photovoltaic layer 130. The second conductive layer 150 is physically connected to the first conductive layer 120 through the second openings 132. In this embodiment, the method of forming the third openings 152 is by patterning the second conductive layer 150 with a laser process, for example. Accordingly, back electrodes of the plurality of sub cells connected in series are formed. The manufacturing method of the thin film solar cell 100 is thus completed.

It is noted that in one case, the second conductive layer 140 is a stacked structure of a transparent conductive layer and a reflective layer, and the first conductive layer 120 is a transparent conductive layer. Herein, a transparent conductive layer is formed on the photovoltaic layer 130, and a reflective layer is then formed on the transparent conductive layer. Thereafter, the process step in FIG. 3I is performed so as to form a thin film solar cell with one-sided illumination. In another case, the first conductive layer 120 can be a stacked structure of a transparent conductive layer and a reflective layer, so as to form another thin film solar cell with one-sided illumination. The manufacturing method has been described above, and the details are not iterated herein. It is noted that the second conductive layer 150 can only be a transparent conductive layer.

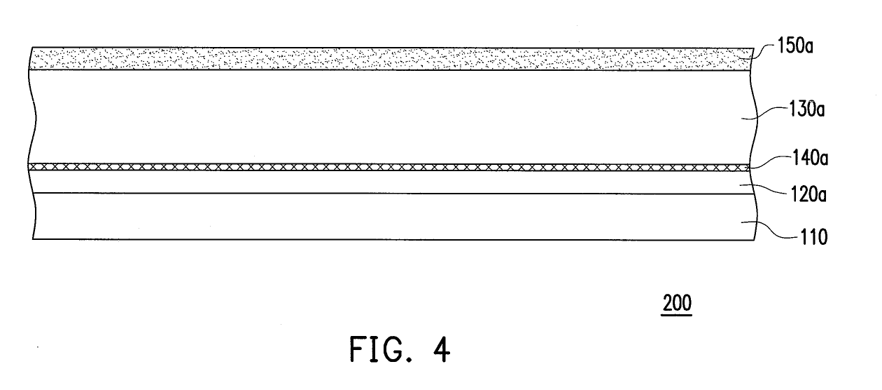

In addition, another thin film solar cell 200 is provided, as shown in FIG. 4. FIG. 4 schematically illustrates a cross-sectional view of a thin film solar cell according to another embodiment of the present invention. Referring to FIG. 1 and FIG. 4, the thin film solar cell 200 is similar to the thin film solar cell 100, and the difference between them lies in that the first conductive layer 120a, the interlayer 140a, the photovoltaic layer 130a and the second conductive layer 150a of the thin film solar cell 200 do not have the above-mentioned openings. That is, the thin film solar cell 200 is designed as a single sub cell only, not a plurality of sub cells connected in series as shown in FIG. 1. Moreover, the thin film solar cell 200 has the interlayer 140a, and the interlayer 140a and the above-mentioned interlayer 140 have the same material and thickness. Therefore, the thin film solar cell 200 also has the advantages of the above-mentioned thin film solar cell 100, and the details are not iterated herein.

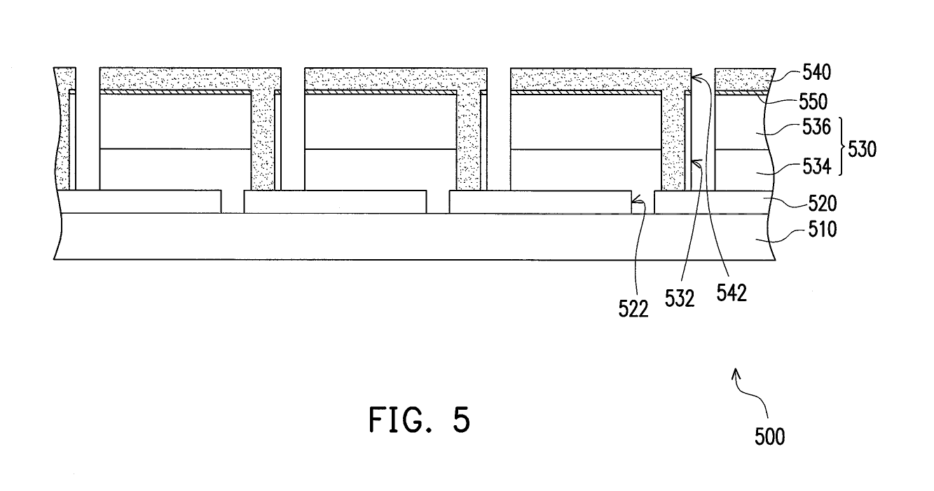

FIG. 5 schematically illustrates a cross-sectional view of a thin film solar cell according to an embodiment of the present invention. Referring to FIG. 5, the thin film solar cell 500 includes a substrate 510, a first conductive layer 520, a photovoltaic layer 530, a second conductive layer 540 and a protection layer 550. In this embodiment, the transparent 510 can be a transparent substrate, such as a glass substrate.

The first conductive layer 520 is disposed on the substrate 510 and has a plurality of first openings 522 to expose a portion of the substrate 510. The first conductive layer 520 usually serves as front electrodes of a plurality of sub cells connected in series. In this embodiment, the first conductive layer 520 can be a transparent conductive layer and the material thereof can include the material of the above-mentioned first conductive layer 120, and the details are not iterated herein.

Further, the first conductive layer 520 can also be a stacked layer of a reflective layer (not shown) and the above-mentioned transparent conductive layer, and the reflective layer is disposed between the transparent conductive layer and the substrate 510. The material of the reflective layer can be metal with higher reflectivity, such as aluminium (Al), silver (Ag), molybdenum (Mo) or copper (Cu).

The photovoltaic layer 530 is disposed on the first conductive layer 500 and has a plurality of second openings 532 to expose a portion of the first conductive layer 520. The photovoltaic layer 530 is physically connected to the substrate 510 through the first openings 522. In this embodiment, the photovoltaic layer 530 can be the above-mentioned Group IV thin film, III-V compound semiconductor thin film, II-VI compound semiconductor thin film or organic compound semiconductor thin film, and the details are not iterated herein.

In other words, the thin film solar cell 500 of this embodiment can include the film layer structure of an amorphous silicon thin film solar cell, a microcrystalline silicon thin film solar cell, a tandem thin film solar cell, a triple thin film solar cell, a CIS thin film solar cell, a GIGS thin film solar cell, a GdTe thin film solar cell or an organic thin film solar cell. The photovoltaic layer 530 of this embodiment is provided only for illustration purposes, and can be decided according to the users' requirements. The thin film solar cell 500 can also include the film layer structure of another suitable thin film solar cell.

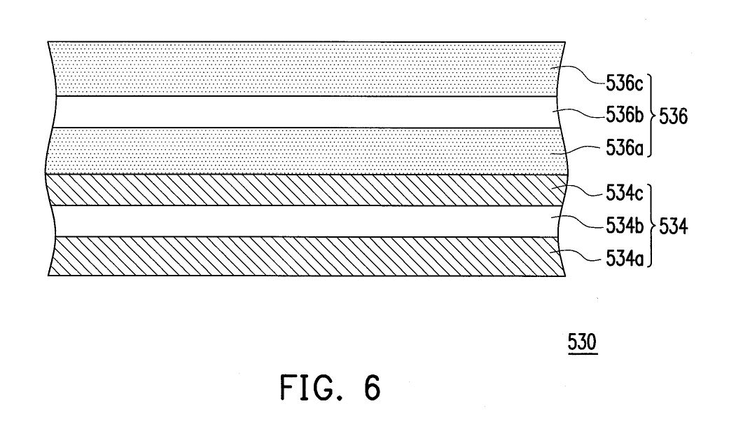

Referring to FIG. 6, when a tandem thin film solar cell is taken as an example, the photovoltaic layer 530 can be a first semiconductor stacked layer 534 with a second semiconductor stacked layer 536 stacked thereon. The first semiconductor stacked layer 534 has a first-type semiconductor layer 534a, a second-type semiconductor layer 534b and a first intrinsic layer 534c, for example. The second semiconductor stacked layer 536 has a third-type semiconductor layer 536a, a fourth-type semiconductor layer 536b and a second intrinsic layer 536c, for example. The first-type semiconductor layer 534a of the first semiconductor stacked layer 534 and the third-type semiconductor layer 536a of the second semiconductor stacked layer 536 can be P-type semiconductor layers, while the third-type semiconductor layer 534b of the first semiconductor stacked layer 534 and the fourth-type semiconductor layer 536b of the second semiconductor stacked layer 536 can be N-type semiconductor layers. In other words, in this embodiment, the first semiconductor stacked layer 534 and the second semiconductor stacked layer 536 form a PIN semiconductor stacked structure. However, the present invention is not limited thereto.

In another embodiment, the first-type semiconductor layer 534a of the first semiconductor stacked layer 534 and the third-type semiconductor layer 536a of the second semiconductor stacked layer 536 can be N-type semiconductor layers, while the third-type semiconductor layer 534b of the first semiconductor stacked layer 534 and the fourth-type semiconductor layer 536b of the second semiconductor stacked layer 136 can be P-type semiconductor layers. In addition, in another embodiment, the first semiconductor stacked layer 534 and the second semiconductor stacked layer 536 described above do not have the first intrinsic layer 534c and the second intrinsic layer 536c and form a PN semiconductor stacked structure.

Referring to FIG. 5, the second conductive layer 540 is disposed on the photovoltaic layer 530 and has a plurality of third openings 542 to expose a portion of the first conductive layer 520 and a portion of the side surface of the photovoltaic layer 530. The third openings 542 and a portion of the second openings 532 are disposed at the same positions, and the second conductive layer 540 is physically connected to the first conductive layer 520 through the second openings 532. Further, the second conductive layer 540 can include the material of the above-mentioned transparent conductive layer, and the details are not iterated herein. In this embodiment, the second conductive layer 540 can further include a reflective layer disposed on the transparent conductive layer.

It is noted that when the second conductive layer 540 includes a reflective layer, the first conductive layer 520 can only be a transparent conductive layer. On the contrary, when the first conductive layer 520 includes a reflective layer, the second conductive layer 540 can only be a transparent conductive layer without a reflective layer thereon. In another embodiment, each of the first conductive layer 520 and the second conductive layer 540 can be a single transparent conductive layer without a reflective layer thereon. In other words, the design of the first conductive layer 520 and the second conductive layer 540 can be adjusted by the users' requirements (e.g. for manufacturing a thin film solar cell with double-sided illumination or a thin film solar cell with one-sided illumination). The design of the first conductive layer 520 and the second conductive layer 540 described above is provided only for illustration purposes, and is not construed as limiting the present invention.

The protection layer 550 is disposed on the photovoltaic layer 530, opposite to the first conductive layer 520 and between the photovoltaic layer 530 and the second conductive layer 540, as shown in FIG. 5. In this embodiment, the protection layer 550 is mainly for reducing the possibility of the surface recombination of electron-hole pairs at the interface between the photovoltaic layer 530 and the second conductive layer 540, and thus, the electrical performance and the photoelectric conversion efficiency of the thin film solar cell 500 are improved. In details, the so-called dangling bonds are present on the surface of the photovoltaic layer 530 in contact with the second conductive layer 540. Further, the electron-hole pairs excited by illumination on the photovoltaic layer 530 are recombined with the dangling bonds on the surface of the photovoltaic layer 130, so as to limit the electrical performance and photovoltaic conversion efficiency of the thin film solar cell 500. In this embodiment, the protection layer 150 is disposed between photovoltaic layer 530 and the second conductive layer 540, so as to reduce or lower the generation of the dangling bonds. Accordingly, surface recombination of the electron-hole pairs at the interface between photovoltaic layer 530 and the second conductive layer 540 is avoided, and the above-mentioned advantages are further achieved.

In this embodiment, the protection layer 550 has better performance as the thickness thereof is substantially more than zero angstrom and less than or equal to 1,000 angstroms. The material of the protection layer 550 can be a dielectric material, an insulating material or an oxygen-containing compound. Specifically, the material of the protection layer 550 can be an insulating material such as silicon oxide, silicon nitride or silicon oxynitride.

In view of the above, the thin film solar cell 500 is irradiated by light (not shown) to generate electron-hole pairs. The thin film solar cell 500 has the protection layer 550 disposed between the photovoltaic layer 530 and the second conductive layer 540, and the protection layer 550 can effectively reduce or lower the dangling bonds on the surface of the photovoltaic layer 530. Accordingly, the possibility of the recombination of the electron-hole pairs at the interface between the photovoltaic layer 530 and the second conductive layer 540 is decreased. In other words, as compared with the conventional thin film solar cell without the protection layer 550, the thin film solar cell 500 with the protection layer 550 obtains a significant improvement in the photoelectric conversion efficiency and electrical performance.

In addition, the present invention also provides a manufacturing method to form the above-mentioned thin film solar cell 500, which is described in the following.

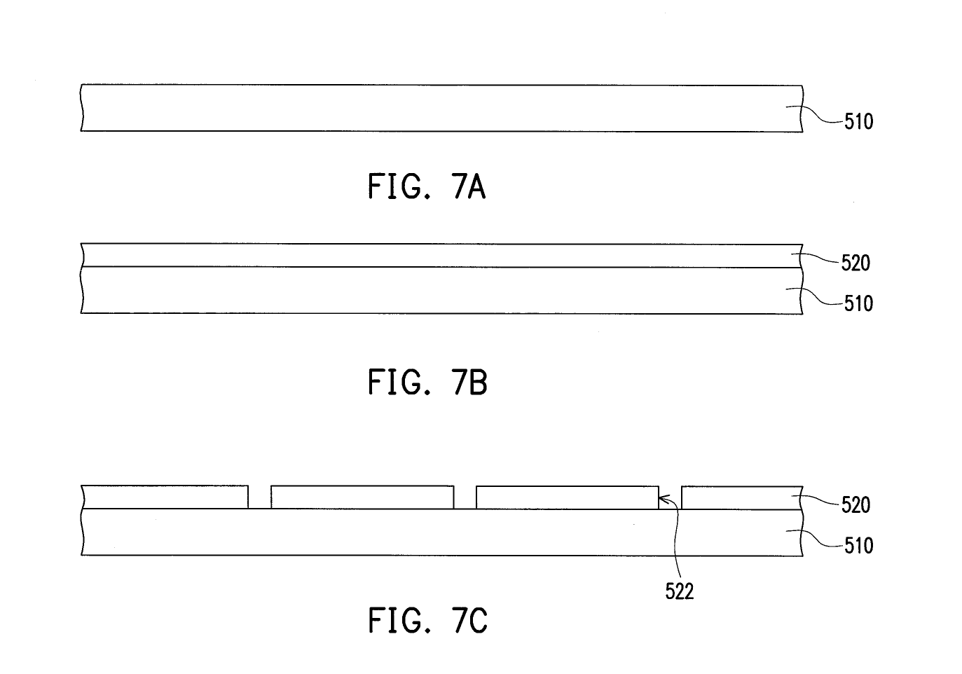

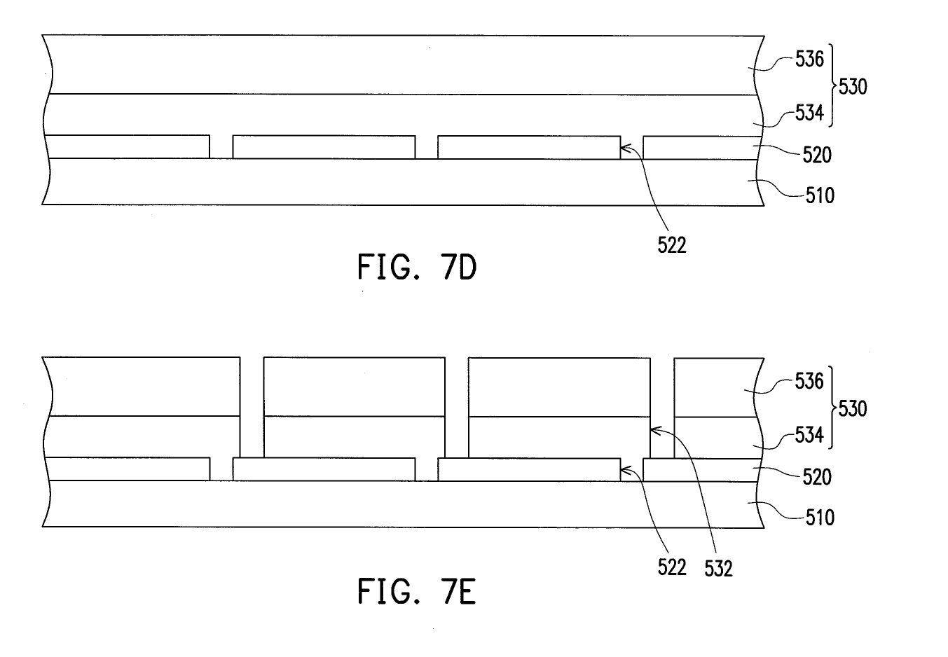

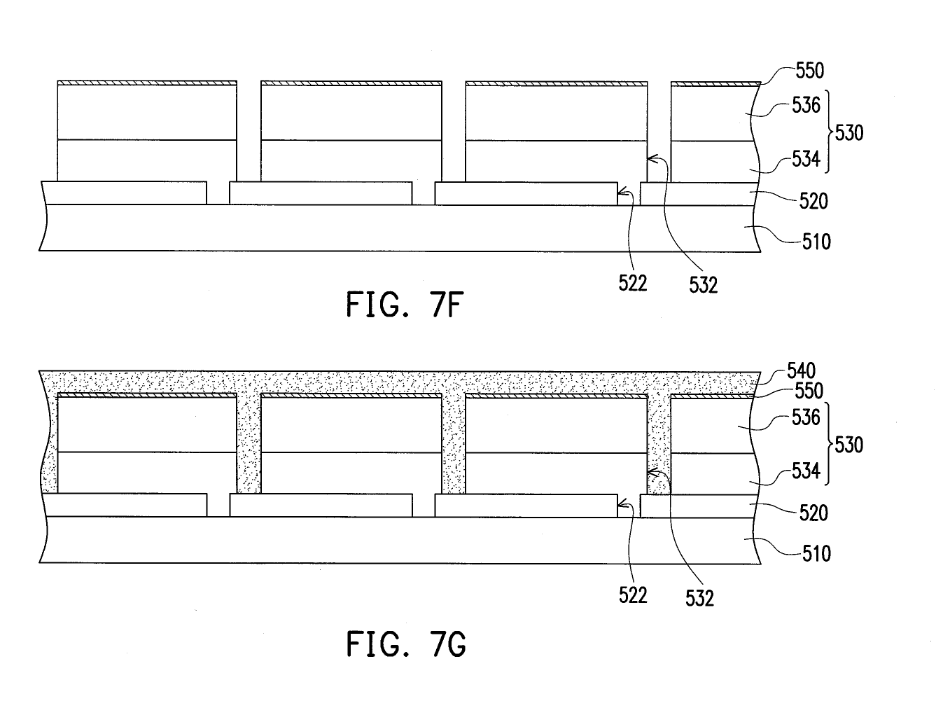

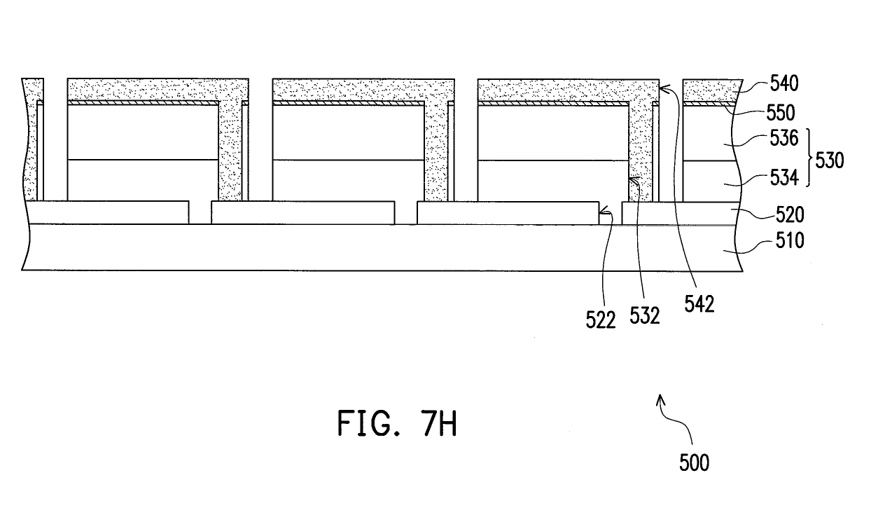

FIGS. 7A to 7H schematically illustrate a process flow of manufacturing a thin film solar cell according to an embodiment of the present invention. Referring to FIG. 7A, the above-mentioned substrate 510 is provided. The substrate 510 can be a transparent substrate, such as a glass substrate.

Referring to FIG. 7B, the above-mentioned first conductive layer 520 is formed on the substrate 510. The first conductive layer 520 includes the material of the above-mentioned transparent conductive layer, and the forming method thereof is by performing a sputtering process, a metal organic chemical vapour deposition (MOCVD) process or an evaporation process, for example.

Referring to FIG. 7C, the above-mentioned first openings 522 are formed in the first conductive layer 520 to expose a portion of the substrate 510. Accordingly, front electrodes of a plurality of sub cells connected in series are formed. In this embodiment, the method of forming the first openings 522 is by patterning the first conductive layer 520 with a laser process, for example.

Referring to FIG. 7D, the above-mentioned photovoltaic layer 530 is formed on the first conductive layer 520. In this embodiment, the method of forming the photovoltaic layer 530 includes forming the above-mentioned first semiconductor stacked layer 534 on the first conductive layer 520, and then forming the above-mentioned second semiconductor stacked layer 536 on the first semiconductor stacked layer 534. In details, the method of forming the photovoltaic layer 530 is by performing a radio frequency plasma enhanced chemical vapour deposition (RF PECVD) process, a vary high frequency plasma enhanced chemical vapour deposition (VHF CVD) process or a microwave plasma enhanced chemical vapour deposition (MW PECVD) process, for example. The above-mentioned forming method of the photovoltaic layer 530 is provided only for illustration purposes, and is not construed as limiting the present invention. The forming method of the photovoltaic layer 530 can be adjusted depending on the film layer design (e.g. the structure of the above-mentioned Group IV thin film or II-VI compound semiconductor thin film) of the photovoltaic layer 530. Further, the deposition thicknesses of the first semiconductor stacked layer 534 and the second semiconductor stacked layer 536 can be decided according to the users' requirements.

Referring to FIG. 7E, the above-mentioned second openings 532 are formed in the photovoltaic layer 530 to expose a portion of the first conductive layer 520. The first semiconductor stacked layer 534 of the photovoltaic layer 530 is physically connected to the substrate 510 through the first openings 532. In this embodiment, the method of forming the second openings 532 is by patterning the photovoltaic layer 530 with a laser process, for example.

Referring to FIG. 7F, the above-mentioned protection layer 550 is formed on the photovoltaic layer 530. In this embodiment, the method of forming the protection layer 550 is by performing a plasma oxidation process (e.g. CO₂ plasma treatment) to the photovoltaic layer 530, so as to form the protection layer 550. In this embodiment, in the CO₂ plasma treatment, the process parameters such as time, gas pressure, output power can be changed to adjust the thickness of the protection layer 550. In this embodiment, the thickness of the protection layer 550 is substantially more than zero angstrom and less than or equal to 1,000 angstroms.

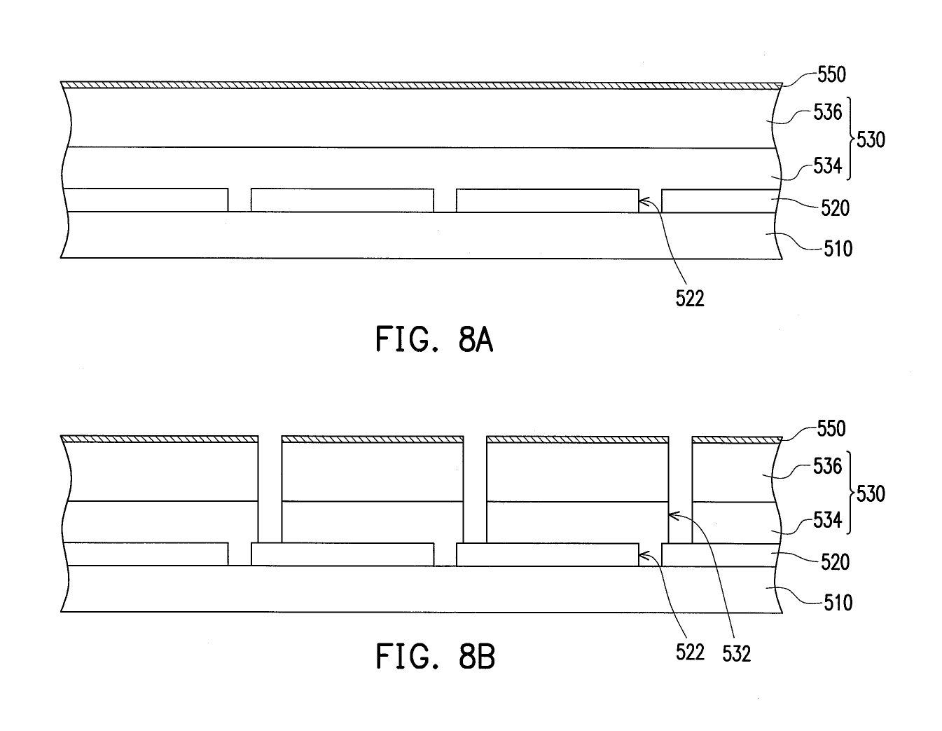

It is noted that in the process steps of this embodiment, the second openings 532 are formed in the photovoltaic layer 530, and then the CO₂ plasma treatment is performed to the photovoltaic layer 530, so as to form the protection layer 550. However, the present invention is not limited thereto. In another embodiment, after the photovoltaic layer 530 is formed, the CO₂ plasma treatment is performed thereto or the photovoltaic layer 530 is exposed to air, so as to form the protection layer 550 on the photovoltaic layer 530, as shown in FIG. 8A. Thereafter, the second openings 532 are formed in the photovoltaic layer 530, as shown in FIG. 8B. The technique scheme described in FIGS. 8A and 8B belongs to the present invention without departing from the spirit and scope of the present invention.

Referring to FIG. 7G, the above-mentioned second conductive layer 540 is formed on the protection layer 550 and in the second openings 532, and covers the portion of the first conductive layer 520 exposed by the second openings 532. In this embodiment, the second conductive layer 540 and the first conductive layer 520 have the same forming method. That is, the method of forming the second conductive layer 540 is by performing the above-mentioned sputtering process, MOCVD process, or evaporation process, for example. The material of the second conductive layer 540 is the material of the above-mentioned transparent conductive layer, and the details are not iterated herein.

Referring to FIG. 7H, the above-mentioned third openings 542 are formed in the second conductive layer 540 to expose a portion of the first conductive layer 520 and a portion of the side surface of the photovoltaic layer 530. The second conductive layer 540 is physically connected to the first conductive layer 520 through the second openings 532. In this embodiment, the method of forming the third openings 542 is by patterning the second conductive layer 540 with a laser process, for example. Accordingly, back electrodes of the plurality of sub cells connected in series are formed.

In one case, the second conductive layer 540 is a stacked structure of a transparent conductive layer and a reflective layer, and the first conductive layer 520 is a transparent conductive layer. Herein, a transparent conductive layer is formed on the photovoltaic layer 530, and a reflective layer is then formed on the transparent conductive layer. Thereafter, the process step in FIG. 7H is performed so as to form a thin film solar cell with one-sided illumination. In another case, the first conductive layer 520 can be a stacked structure of a transparent conductive layer and a reflective layer, so as to form another thin film solar cell with one-sided illumination. The manufacturing method has been described above, and the details are not iterated herein. It is noted that the second conductive layer 540 can only be a transparent conductive layer.

In summary, the thin film solar cell of the present invention and the manufacturing method thereof at least have the following advantages. First, since the thin film solar cell has the interlayer between the photovoltaic layer and the first conductive layer, the interlayer can reduce the dangling bonds on the surface on the photovoltaic layer to decrease the possibility of the recombination of electron-hole pairs on the surface on the photovoltaic layer, and thus, the photoelectric characteristics and photoelectric conversion efficiency of the thin film solar cell can be improved. Besides, in the manufacturing method of the present invention, a simple process step can be performed to form the above-mentioned interlayer, so as to form the above-mentioned thin film solar cell.

In addition, the thin film solar cell of the present invention and the manufacturing method thereof at least have the following advantages. First, the thin film solar cell has the protection layer between the photovoltaic layer and the second conductive layer, so that the dangling bonds on the surface of the photovoltaic layer in contact with the second conductive layer are reduced, the possibility of the recombination of electron-hole pairs on the contact surface between the film layers is decreased, and the photoelectric characteristics of the thin film solar cell is further improved. In other words, the thin film solar cell of the present invention has higher photoelectric conversion efficiency. Similarly, in the manufacturing method of the present invention, a simple process step can be performed to form the above-mentioned protection layer, so as to improve the performance of the thin film solar cell.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A thin film solar cell, comprising:
a substrate;
a first conductive layer, disposed on the substrate;
a photovoltaic layer, disposed on the first conductive layer, wherein a plurality of electron-hole pairs are generated as the photovoltaic layer is illuminated;
an interlayer, disposed between the first conductive layer and the photovoltaic layer and reducing dangling bonds on a surface of the photovoltaic layer to prevent surface recombination of the electron-hole pairs from occurring on the surface of the photovoltaic layer; and
a second conductive layer, disposed on the photovoltaic layer.

2. The thin film solar cell of claim 1, wherein a thickness of the interlayer is more than zero angstrom and less than or equal to 1,000 angstroms.

3. The thin film solar cell of claim 2, wherein a material of the interlayer is a dielectric material, an insulating material or an oxygen-containing compound.

4. The thin film solar cell of claim 3, wherein the material of the interlayer comprises silicon oxide, silicon nitride or silicon oxynitride.

5. The thin film solar cell of claim 1, wherein the photovoltaic layer is a Group IV thin film, a III-V compound semiconductor thin film, a II-VI compound semiconductor thin film or an organic compound semiconductor thin film.

6. A manufacturing method of a thin film solar cell, comprising:
providing a substrate;
forming a first conductive layer on the substrate;
forming an interlayer on the first conductive layer;
forming a photovoltaic layer on the interlayer, wherein the interlayer disposed between the first conductive layer and the photovoltaic layer reduces dangling bonds on a surface of the photovoltaic layer to prevent surface recombination of electron-hole pairs from occurring on the surface of the photovoltaic layer; and
forming a second conductive layer on the photovoltaic layer.

7. The manufacturing method of claim 6, further comprising, after the step of forming the interlayer on the first conductive layer, performing a laser process to pattern the interlayer and the first conductive layer, so as to form a plurality of first openings to expose the substrate.

8. The manufacturing method of claim 6, further comprising, before the step of forming the interlayer on the first conductive layer, performing a laser process to pattern the first conductive layer, so as to form a plurality of first openings to expose the substrate.

9. The manufacturing method of claim 6, wherein a method of forming the interlayer comprises performing an oxidation process or a deposition process.

10. The manufacturing method of claim 6, further comprising, after the step of forming the photovoltaic layer on the first conductive layer, performing a laser process to pattern the photovoltaic layer, so as to form a plurality of second openings to expose the first conductive layer.

11. The manufacturing method of claim 6, further comprising, after the step of forming the second conductive layer on the photovoltaic layer, performing a laser process to pattern the photovoltaic layer and the second conductive layer, so as to form a plurality of third openings to expose the first conductive layer.

12. The manufacturing method of claim 6, wherein a method of forming the interlayer comprises performing a plasma oxidation process.

13. The manufacturing method of claim 6, wherein a method of forming the interlayer comprises performing a deposition process, a print screening process, a dry film lamination process or a coating process.

14. A thin film solar cell, comprising:
a substrate,
a first conductive layer, disposed on the substrate and having a plurality of first openings to expose a portion of the substrate;
a photovoltaic layer, disposed on the first conductive layer and having a plurality of second openings to expose a portion of the first conductive layer, wherein the photovoltaic layer is physically connected to the substrate through the first openings;
a second conductive layer, disposed on the photovoltaic layer and having a plurality of third openings to expose a portion of the first conductive layer and a portion of a side surface of the photovoltaic layer, wherein the third openings and a portion of the second openings are disposed at the same positions, and the second conductive layer is physically connected to the first conductive layer through the second openings; and
a protection layer, disposed on the photovoltaic layer, opposite to the first conductive layer and between the photovoltaic layer and the second conductive layer.

15. The thin film solar cell of claim 14, wherein a thickness of the protection layer is more than zero angstrom and less than or equal to 1,000 angstroms.

16. The thin film solar cell of claim 15, wherein a material of the protection layer is a dielectric material, an insulating material or an oxygen-containing compound.

17. The thin film solar cell of claim 15, wherein the material of the protection layer comprises silicon oxide, silicon nitride or silicon oxynitride.

18. The thin film solar cell of claim 14, wherein the photovoltaic layer is a Group IV thin film, a compound semiconductor thin film, a II-VI compound semiconductor thin film or an organic compound semiconductor thin film.
